(19) United States
(12) Patent Application Publication
(10) Pub. No.: US 2005/0161319 A1
(43) Pub. Date: Jul. 28, 2005

(54) Manufacturing method for optical recording medium, and manufacturing device thereof

(75) Inventor: Tetsuo Hosokawa, Kawasaki (JP)

Correspondence Address: Patrick G. Burns, Esq.;GREER, BURNS & CRAIN, LTD., Suite 2500, 300 South Wacker Dr., Chicago, IL, 60606, US

(73) Assignee: FUJITSU LIMITED

(21) Appl. No.: 11/086,521

(22) Filed: Mar. 22, 2005

Related U.S. Application Data
(63) Continuation of application No. PCT/JP03/02889, filed on Mar. 12, 2003.

(51) Int. Cl. C23C 14/32

(52) U.S. Cl. 204/192.2; 204/298.07; 204/192.26

(57) ABSTRACT

A magneto-optical recording medium where an optical recording film is formed on optical phase pits formed on a substrate can be optically regenerated both the optical phase pit signals and the signals of the recording film formed thereon. The modulation degree of the phase pits is adjusted by changing the gas pressure when the recording film is deposited on the substrate by sputtering. By this, an optical storage medium, of which the jitter of RAM signals and the phase pit signals are suppressed to the target 10% or less, can be uniformly manufactured at low cost.

### CROSS-REFERENCE TO RELATED APPLICATIONS

This application is a continuation of international application PCT/JP03/002889, filed on Mar. 12, 2003.

### TECHNICAL FIELD

The present invention relates to a manufacturing method for an optical recording medium which has both functions of ROM (Read Only Memory) by optical phase pits formed on a substrate and RAM (Random Access Memory) by an optically readable recording film, and a manufacturing device thereof, and more particularly to a manufacturing method for an optical recording medium for regenerating both the ROM and RAM well and a manufacturing device thereof.

### BACKGROUND ART

The progress of optical recording media is remarkable, and in addition to such ROM (Read Only Memory) as CD-ROM and DVD-ROM, such RAM (Random Access Memory) as CD-RW, DVD-RW and MO (magneto-optical disk) are also used.

FIG. 18 is a plan view depicting a conventional magneto-optical disk conforming to ISO standards, FIG. 19 is an enlarged view depicting the user area thereof, FIG. 20 is a cross-sectional view thereof, and FIG. 21 is a relational diagram depicting the phase pits thereof and an MO signal. As FIG. 18 shows, the magneto-optical disk 70 is comprised of a read in area 71, read out area 72 and user area 73. The read in area 71 and the read out area 72 are ROM areas comprised of phase pits formed by bumps on the polycarbonate substrate. The depths of the phase pits of the ROM area are set such that the light intensity modulation during regeneration becomes the maximum. The area between the read in area 71 and the read out area 72 is the user area 73, which is a RAM area where the user can freely record information.

As the enlarged view of the user area 73 in FIG. 19 shows, the land 75 between the grooves 74, to be the tracking guides, has phase pits 78 to be a header section 76 and user data section 77. The user data section 77 is a flat land 75 between the grooves 74, and is recorded as magneto-optical signals.

To read the magneto-optical signals, when a weak laser beam is emitted there, the polarization plane of the laser beam changes depending on the magnetization direction of the recording layer by the polar Kerr effect, and the presence of a signal is judged by the intensity of the polarization component of the reflected light at this time. By this the RAM information can be read.

Research and development to utilize such features of this magneto-optical disk memory have been advancing. For example, in Japanese Patent Application Laid-open No. H6-202820, a concurrent ROM-RAM optical disk which can regenerate ROM and RAM simultaneously was disclosed.

Such a magneto-optical recording medium 74 which can regenerate ROM and RAM simultaneously has a cross-sectional structure in the radius direction shown in FIG. 20, and is comprised, for example, of a substrate 74A made of polycarbonate, dielectric film 74B, magneto-optical recording film 74C made of TbFeCo, dielectric film 74D, Al film 74E, and UV hardening film 74F as a protective layer, which are layered.

In this magneto-optical recording medium with such a structure, as shown in FIGS. 20 and 21, the ROM information is fixedly recorded by the phase pits PP on the substrate 74A, and the RAM information OMM is recorded on the phase pit PP string by magneto-optical recording. FIG. 21 is the cross-section in the A-B line in the radius direction in FIG. 20. In the example shown in FIG. 21, the phase pits PP become the tracking guides, so the grooves 74 shown in FIG. 19 are not provided.

Such an optical information recording medium having ROM information and RAM information on a same recording surface is not limited to a magneto-optical recording medium, but is also proposed for an optical recording medium having a recording layer using phase change.

In this optical recording medium, many problems exist to simultaneously regenerate ROM information comprised of phase pits PP and RAM information comprised of magneto-optical recording OMM.

First in order to stably regenerate ROM information along with RAM information, the light intensity modulation which occurs when ROM information is read becomes a cause of noise when RAM information is regenerated. For this the present applicant proposed to decrease the light intensity modulation noise by the negative feedback of the light intensity modulation signals, generated when ROM information is read, to the laser for read driving in the international application PCT/JP 02/00159 (international application filing date Jan. 11, 2002). However a noise reduction effect is not sufficient with only this if the light intensity modulation degree of the ROM information is high.

Secondly the feedback control of the laser intensity at high-speed is difficult.

To solve these problems, the present inventors proposed a method for reducing the jitter of MO signals on the ROM by phase pit shapes and by adjusting the phase pit modulation degree (PCT/JP 02/08774, international application filing date Aug. 30, 2002).

The depth and angle of the phase pits can be adjusted by the resist film thickness adjustment in the manufacturing step of stamper for forming phase pits on the substrate or in the step process conditions such as DUV (Deep Ultraviolet) irradiation processing to the stamper and substrate. However it is virtually impossible to manufacture phase pits that always have a predetermined shape.

Even if the manufacturing conditions are constant, the pit shapes of the completed stamper always disperse depending on various fluctuation factors generated in the manufacturing steps. If the phase pit shapes of the stamper disperse, the phase pit shapes of the substrate, which are molded using the stamper, always disperse, and the modulation degree fluctuates.

Also a stamper is expensive, and disposal, due to irregularities, causes enormous losses. One method of correcting the phase pit shapes of the stamper is irradiating DUV onto the molded substrate where the phase pits are molded. By this DUV irradiation onto the substrate, it is possible to process phase pit shapes and to adjust the modulation degree.

However with this manufacturing method, new DUV processing equipment is required and the processing time become lengthy, so the productivity of the ROM-RAM optical recording medium drops dramatically. As a result, the manufacturing cost of the ROM-RAM optical recording medium rises, which may impede the popularization of such ROM-RAM optical recording medium.

### SUMMARY OF THE INVENTION

With the foregoing in view, it is an object of the present invention to provide a manufacturing method for an optical recording medium for improving the productivity of an optical recording medium which stably regenerates the ROM information comprised of phase pits and the RAM information by an optical recording layer simultaneously, and to provide a manufacturing device thereof.

It is another object of the present invention to provide a manufacturing method for decreasing the manufacturing cost of an optical recording medium which can suppress the jitter of the regeneration signals of the ROM information and RAM information within a predetermined range, and a manufacturing device thereof.

It is still another object of the present invention to provide a manufacturing method for an optical recording medium for providing an optical medium which suppresses the jitter of the regeneration signals of the ROM information and RAM information within a predetermined range without generating cracks with a sufficient repeat recording durability.

To achieve these objects, the manufacturing method for an optical recording medium of the present invention is a manufacturing method for an optical recording medium where a recording film is formed on optical phase pits formed on a substrate so that both the optical phase pit signals and the signals of the recording film can be regenerated by light. The method includes a step of depositing the recording film by sputtering on the substrate on which the phase pits are formed by introducing inactive gas into a chamber, and a step of depositing a reflection layer by sputtering on the substrate on which the recording film is formed, and the light modulation degree of the phase pits is adjusted by changing the pressure of the inactive gas in the chamber when the recording film is deposited by sputtering.

According to the present invention, the light modulation degree of the phase pits is adjusted by the pressure of the inactive gas when the recording film is deposited by sputtering, so the productivity of the optical recording medium, which stably regenerates the ROM information by phase pits and RAM information by the optical recording layer simultaneously, can be improved, and the manufacturing cost can be decreased.

According to the present invention, it is preferable that the step of depositing the recording film by sputtering further includes a step of changing the light modulation degree of the phase pits by depositing an undercoat layer of the recording film on the substrate by sputtering with changing the pressure of the inactive gas in the chamber, and a step of depositing the recording film by sputtering on the substrate on which the undercoat layer was formed.

Since the pressure of the inactive gas is changed in the sputtering step for the undercoat layer, a stable recording film can be obtained without changing the sputtering conditions of the recording film.

According to the present invention, it is preferable that the undercoat layer of the recording film deposited by sputtering is a dielectric layer.

Also according to the present invention, it is preferable that the undercoat layer of the recording film deposited by the sputtering is SiN.

According to the present invention, it is preferable that the step for depositing the undercoat layer by sputtering is a step of depositing the undercoat layer by introducing at least an Ar gas and hydrogen gas into the chamber.

Also according to the present invention, it is preferable that the step for depositing the undercoat layer by sputtering is a step of depositing the undercoat layer by sputtering with a gas pressure in the chamber in a range of 0.5 to 2.0 Pa.

According to the present invention, it is preferable that the step of depositing the recording film by sputtering further includes a step of depositing a magneto-optical recording film by sputtering.

Also it is preferable that the present invention further includes a step of depositing an overcoat layer on the recording film.

According to the present invention, it is preferable that the step of depositing the undercoat layer by sputtering is a step of depositing the undercoat layer by sputtering under sputtering conditions that satisfy
344X−8.12≧Y and Y≧286X−10.7
0.080≦X≦0.124 and 16≦Y≦30
   where X (λ) is the optical depth of the phase pits formed on the substrate and Y (%) is the modulation degree of the phase pits when irradiated with an optical beam in the polarization direction perpendicular to the tracks of the optical recording medium.

Also according to the present invention, it is preferable that the step of depositing the undercoat layer by sputtering is a step of depositing the undercoat layer by sputtering under sputtering conditions that satisfy the condition 19≦Y≦26 out of the above mentioned conditions in the case of magneto-optical recording film.

### BRIEF DESCRIPTION OF THE DRAWINGS

FIG. 1 is a cross-sectional view depicting the magneto-optical recording medium to be used for an embodiment of the present invention;

FIG. 2 is a perspective view depicting the recording status of the ROM information and RAM information in the magneto-optical recording medium in FIG. 1;

FIG. 3 is a diagram depicting the configuration of the sputtering device for manufacturing the magneto-optical recording medium in FIG. 1;

FIG. 4 is a graph depicting the relationship between the Ar flow rate and pressure in the chamber in FIG. 3;

FIG. 5 is a diagram depicting the configuration of the sputtering film deposition device according to an embodiment of the present invention;

FIG. 6 is a diagram depicting the modulation degree of the phase pits which is the evaluation target of the magneto-optical recording medium of the present invention;

FIG. 7 is a graph depicting the signal jitter which is the evaluation target of the magneto-optical recording medium of the present invention;

FIG. 8 is a graph depicting the relationship between the Ar pressure and modulation degree according to the present invention;

FIG. 9 is a graph depicting the relationship between the modulation degree and jitter of the ROM signal and RAM signal according to the present invention;

FIG. 10 is a graph depicting the relationship between the Ar pressure and signal jitter according to the present invention;

FIG. 11 is a table showing the crack observation result by heat shock testing according to the present invention;

FIG. 12 is a graph depicting the optical phase pit depth and modulation degree according to the present invention;

FIG. 13 is a graph depicting the setup range of the optical phase pit depth and modulation degree according to the present invention;

FIG. 14 is a diagram depicting the configuration of the sputtering film deposition device according to another embodiment of the present invention;

FIG. 15 is a cross-sectional view depicting the magneto-optical recording medium according to another embodiment of the present invention;

FIG. 16 is a cross-sectional view depicting the magneto-optical recording medium according to another embodiment of the present invention;

FIG. 17 is a cross-sectional view depicting the magneto-optical recording medium according to another embodiment of the present invention;

FIG. 18 is a plan view depicting a conventional magneto-optical recording medium;

FIG. 19 is a diagram depicting the user area in FIG. 18;

FIG. 20 is a cross-sectional view depicting the ROM-RAM magneto-optical disk memory shown in FIG. 19; and

FIG. 21 is a plan view depicting the recording status of the ROM information and RAM information in the magneto-optical recording medium with the structure in FIG. 20.

### PREFERRED EMBODIMENTS OF THE INVENTION

Embodiments of the present invention will now be described in the sequence of the ROM-RAM optical recording medium, manufacturing method for the optical recording medium and other embodiments.

ROM-RAM Optical Recording Medium

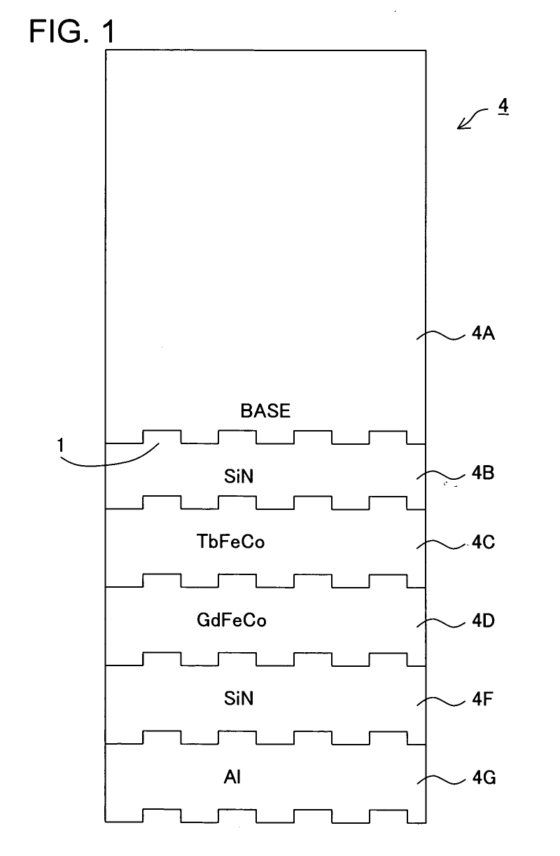

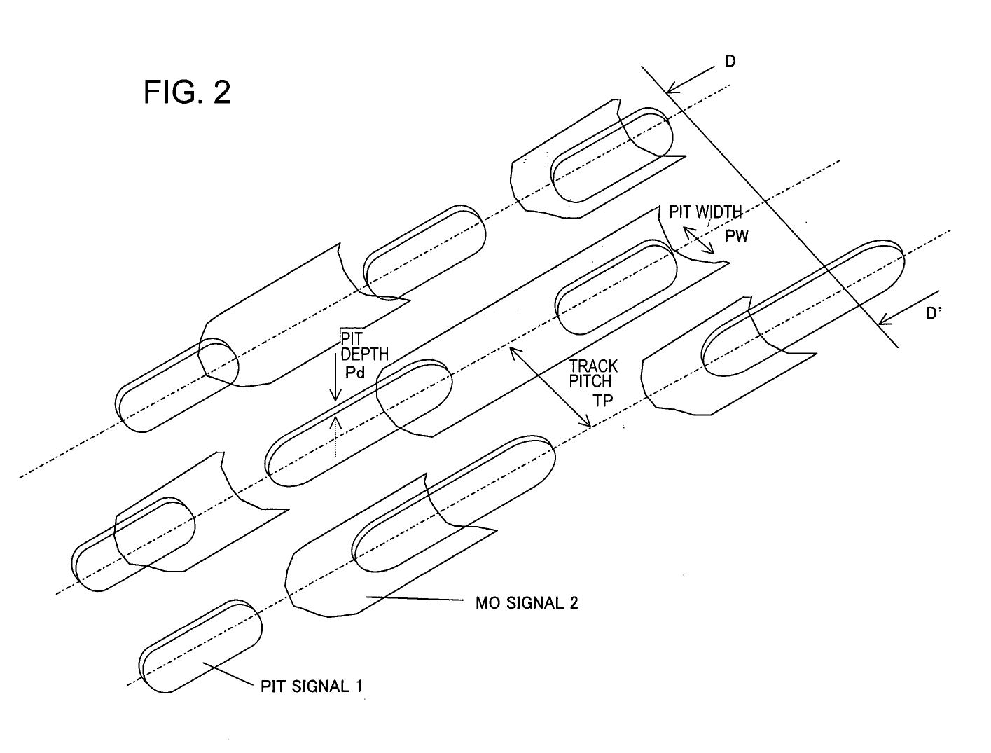

FIG. 1 is a cross-sectional view depicting the concurrent optical recording medium according to an embodiment of the present invention, and FIG. 2 is a diagram depicting the relationship of the ROM signal and the RAM signal thereof. In FIG. 1, a magneto-optical recording medium is described as an example of an optical recording medium.

As FIG. 1 shows, in order to provide the functions of ROM and RAM in the user area, the magneto-optical disk 4 is comprised of a first dielectric layer 4B made from silicon nitride (SiN) or tantalum oxide, two layers of magneto-optical recording layers 4C and 4D of which the main component is an amorphous alloy of a rare earth element (Tb, Dy, Gd) and transition metals (FeCo), such as TbFeCo and GdFeCo, a second dielectric layer 4F made from a material that is the same as or different from that of the first dielectric layer 4B, a reflection layer 4G made from such a metal as Al and Au, and a protective coat layer using ultraviolet hardening resin, which are formed on a polycarbonate substrate 4A on which the phase pits 1 are formed.

As FIG. 1 and FIG. 2 show, the ROM function is provided by the phase pits 1 which are created as bumps on the disk 4, and the RAM function is provided by the magneto-optical recording layers 4C and 4D. To record on the magneto-optical recording layers 4C and 4D, a laser beam is applied onto the magneto-optical recording layers 4C and 4D to assist in the reversal of magnetization, the magneto-optical (MO) signals 2 are recorded by reversing the direction of magnetization corresponding to the signal magnetic field. By this, recording the RAM information is possible.

To read the recorded information of the magneto-optical recording layers 4C and 4D, a weak laser beam is applied onto the recording layers 4C and 4D so that the polarization plane of the laser beam is changed according to the magnetization direction of the recording layers 4C and 4D by the polar Kerr effect, and the presence of signals is judged by the intensity of the polarization component of the reflected light at this time. By this, the RAM information can be read. In this reading, the reflected light is modulated by the phase pits PP constituting ROM, so the ROM information can be read simultaneously.

In other words, ROM and RAM can be simultaneously regenerated by one optical pickup, and when a magnetic field modulation type magneto-optical recording is used, writing to RAM and regenerating ROM can be executed simultaneously.

Manufacturing Method for Optical Recording Medium

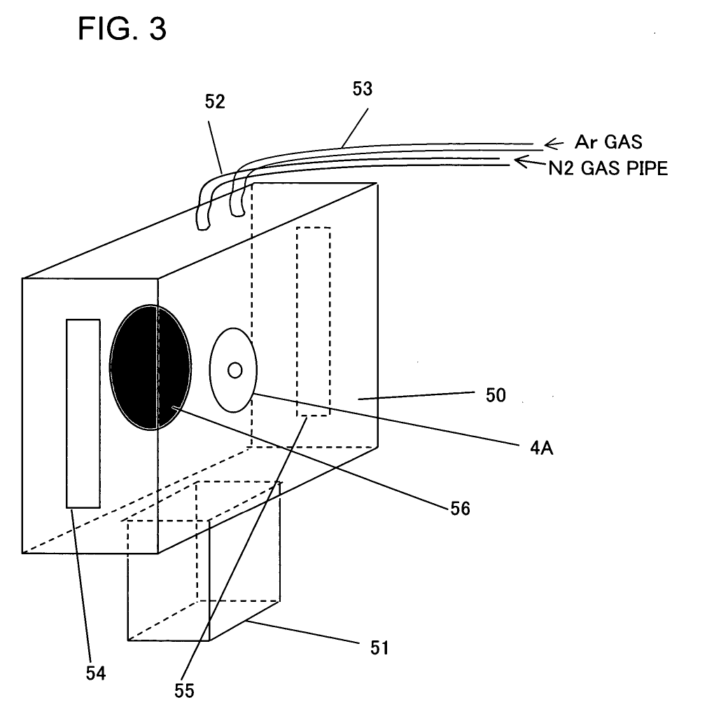

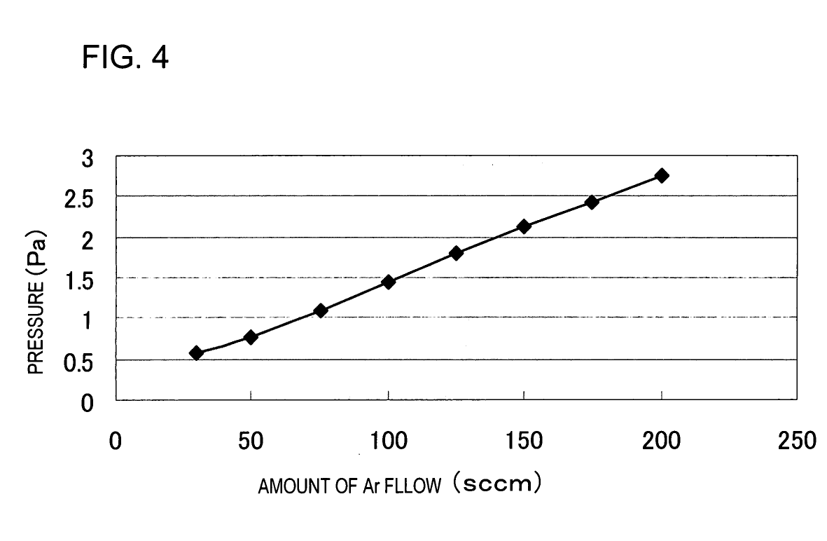

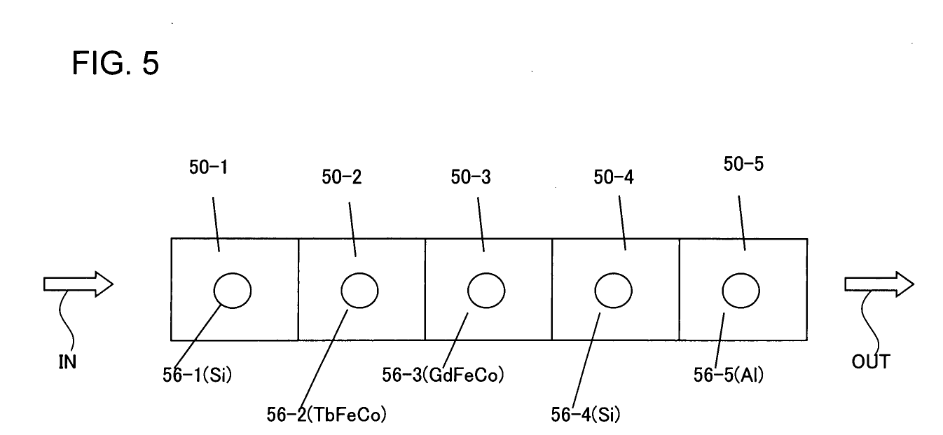

FIG. 3 is a diagram depicting the sputtering device for manufacturing the concurrent magneto-optical medium in FIG. 1, FIG. 4 is a graph depicting the relationship of the Ar flow rate and the pressure in the chamber thereof, and FIG. 5 is a diagram depicting the configuration of the sputtering film deposition device using the sputtering device in FIG. 3.

First the manufacturing step of the magneto-optical disk with the cross-sectional configuration shown in FIG. 1 will be described. Five polycarbonate substrates 4A with different groove depths (optical pit depths) Pd, which are formed with an EFM modulation of track pitch Tp=1.6 μm, pit width Pw=0.40 μm and the shortest pit length=0.832 μm, are prepared according to FIG. 2.

In other words, five polycarbonate substrates 4A of which the optical phase pit depth Pd (λ) is 0.070, 0.080, 0.105, 0.124 and 0.136 are prepared. Here the pit depth is changed by the resist coating film thickness in the stamper manufacturing process of the stamper for forming the phase pits on the substrate 4A.

FIG. 5 is a diagram depicting the configuration of the sputtering film deposition device for manufacturing the magneto-optical medium with the above mentioned film configuration, where five sputtering devices (chambers) 50-1 to 50-5 are linked in a series. The five sputtering devices (chambers) may be arranged in an arc.

The substrate 4A, which is on a carrier, is entered from the left in FIG. 5, and in the five sputtering devices 50-1 to 50-5, the first dielectric layer 4B made from silicon nitride (SiN) or tantalum oxide, two layers of magneto-optical recording layers 4C and 4D of which the main component is an amorphous alloy of a rare earth element (Tb, Dy, Gb) and a transition metal (FeCo), such as TbFeCo and GdFeCo, a second dielectric layer 4F made from the same material as the first dielectric layer 4B, and a reflection layer 4G made from such metals as Al and Au are sequentially deposited on the substrate 4A by sputtering, as shown in the configuration in FIG. 1, and the magneto-optical medium 4 with the configuration in FIG. 1 is ejected to the right direction.

Each sputtering device in FIG. 5 will be described with reference to FIG. 3. As FIG. 3 shows, the sputtering device vacuums inside the sputtering chamber 50 at about 5×e−5 (Pascal), for example, using such a vacuum pump 51 as a cryopump. Then the substrate transport gates 54 and 55 are opened and the substrate 4A is inserted from the adjacent chamber. Ar gas and N₂ gas, which are inactive gases, are introduced into the sputtering chamber 50 via the Ar gas pipe 53 and the N₂ gas pipe 52. At this time the gas pressure in the sputtering chamber 50 is adjusted by changing the flow rate of the Ar gas.

As FIG. 4 shows, the relationship between the Ar gas flow rate and the pressure differs depending on the size and shape of the sputtering chamber 50, but the relationship is roughly proportional. To the target 56, such as Si, power is supplied from a DC power supply, which is not illustrated. Plasma is generated by the supplied power and Ar gas, Si is scattered from the Si target 56, and is deposited on the substrate 4A while reacting with the N₂ gas, and an SiN layer 4B is formed on the substrate 4A as a result.

Now the manufacturing steps of the magneto-optical medium 4 in FIG. 1 will be described with reference to FIG. 5.

The polycarbonate substrate 4A, having phase pits after being baked for five hours at 80° C. to remove moisture, is inserted into the first chamber 50-1 of which the ultimate vacuum is 5×e−5 (Pa) or less. The Ar gas and the N₂ gas are introduced into the first chamber 50-1 where the Si target 56-1 is set, then 3 Kilo watt of DC power is supplied, and the under coat (UC) SiN layer 4B is deposited by reactive sputtering discharge.

By changing the flow rate of the Ar gas at this time, the gas pressure in the sputtering chamber 50 is adjusted. To the Si target 56-1, power is supplied from a DC power supply, which is not illustrated. By the supplied power and Ar gas, plasma is generated, Si is scattered out of the Si target 56-1 and is deposited on the substrate 4A while reacting with the N₂ gas, and the SiN layer 4B is formed on the substrate 4A as a result.

Here a plurality of samples (a total of 42 samples with seven types of gas pressures, as described later), which has the SiN undercoat layer, were created by changing the gas pressure in the chamber 50 by changing the Ar gas flow rate. The gas flow rate was changed in a 30 sccm (quantity that flows per minute) to a 200 sccm range. The film deposition time was adjusted so that the thickness of the under coat SiN layer 4B becomes 80 nm.

Then the substrate 4A is moved to the second chamber 52-2, where the Ar gas is introduced and the power supply is set to 1 Kw and the Ar gas pressure to 0.5 Pa, the alloy target 56-2 made from TbFeCo is discharged, and the recording layer 4C with a 30 nm thickness made from Tb₂₂ (Fe₈₈Co₁₂) 78 is deposited.

Then the substrate 4A is moved to the third chamber 50-3 where the Ar gas is introduced, and the power supply is set to 0.5 Kw, and the Ar gas pressure to 0.5 Pa, the alloy target 56-3 made from Gd₁₉ (Fe₈₀Co₂₀) 81 is discharged, and the Gd₁₉ (Fe₈₀Co₂₀) 81 recording auxiliary layer 4D with a 4 nm film thickness is added to the Tb₂₂ (Fe₈₈Co₁₂) 78 recording layer 4C with a 30 nm film thickness, as shown in FIG. 1.

Then the substrate 4A is moved to the fourth chamber 50-4, and just like the case of the first chamber 50-1, the Ar gas and N₂ gas are introduced, 3 Kw of DC power is supplied, and the over coat SiN layer 4E with a 5 nm thickness is deposited by reactive sputtering discharge. The film deposition conditions of the over coat layer is an Ar flow rate at 75 sccm and N₂ gas flow rate at 33 sccm.

Then the substrate 4A is moved to the fifth chamber 50-5, Ar gas is introduced, and the DC power supply is set to 0.5 Kw and the Ar gas pressure to 0.5 Pa, the Al target 56-5 is discharged, and a 50 nm Al layer 4G is deposited as a result.

After the Al layer is deposited, the substrate 4A is taken out of the sputtering film deposition device 50-5, the ultraviolet hardening resin is spin-coated thereon to form the protective film, and the magneto-optical recording medium 4 shown in FIG. 1 is created.

The modulation degree and the jitter, when the ROM of the 42 samples with this configuration (magneto-optical disks formed on the substrates with six types of optical pit depths using seven different gas pressures) is regenerated, are measured as the evaluation target.

These samples are set in the recording/regeneration device (MO tester: LM 530C made by Shibasoku Ltd.) with a 1.08 μm (1/e 2) beam diameter, a 650 nm wave length and 0.55 NA (Numerical Aperture), and are rotated at a 4.8 m/s line speed

Phase pits (the same pattern as a compact disk) for the EFM modulation of which the shortest mark is 0.832 μm are formed on the ROM section 42 of these samples. The modulation degree is measured as shown in FIG. 5 by recording data under the following recording conditions and regenerating it under the following regeneration conditions. That is, an EFM random pattern is recorded by magnetic field modulation on the ROM section 42 with a Pw=6.5 mW recording laser power and a DC emission with the shortest mark length, 0.832 μm.

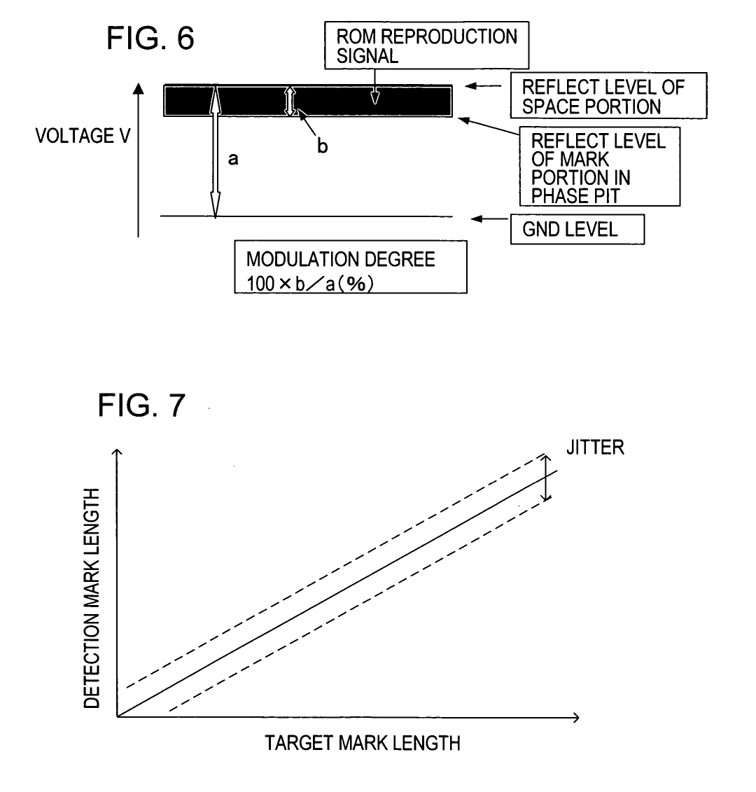

The regenerated light is at regeneration power Pr=1.5 mW and no regeneration magnetic field, and the polarization direction is in a perpendicular direction with respect to the tracks. ROM regeneration waveforms are measured by an oscilloscope, and on the tracks of the medium shown in FIG. 2, the reflection level (space section reflection level in FIG. 6) when the regeneration beam is applied onto the sections where the phase pits 1 do not exist (space sections), and the regeneration output level (mark section reflection level in FIG. 6) when the regeneration beam is applied onto the section where the phase pits 1 exist (mark sections), were measured. As FIG. 6 shows, the modulation degree is defined as 100×b/a(%).

For the jitter, ROM jitter by the phase pits and MO regeneration jitter on the ROM were measured. The jitter shown in FIG. 7 was measured by a time interval analyzer during “data to data” time. The jitter is the size of the error of the detected mark length with respect to the target mark length, and if the jitter is large, error correction becomes impossible, and a regeneration error occurs.

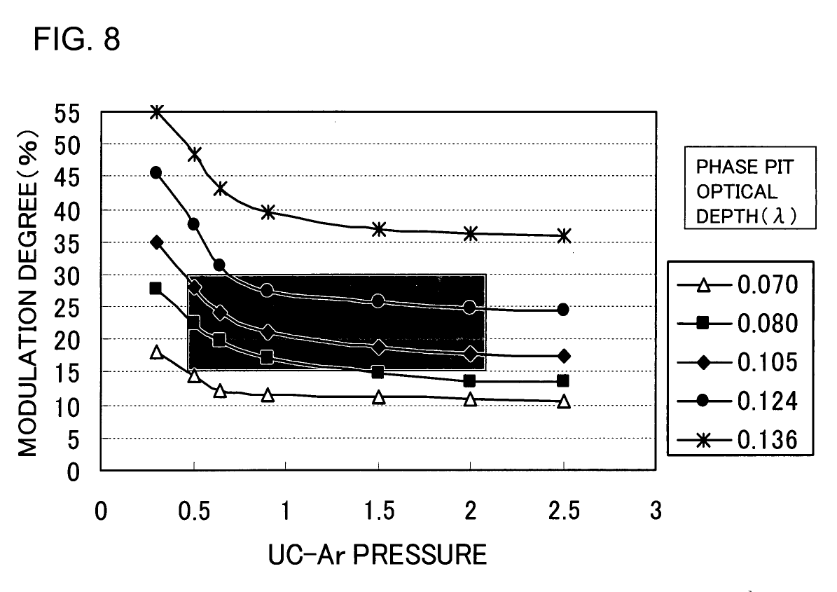

FIG. 8 shows the dependency of the modulation degree on the Ar pressure when an SiN undercoat layer is formed for each substrate (five types of substrates) of which the depth of the phase pits is different. As FIG. 8 shows, the modulation degree can be adjusted to be high at a low Ar pressure side, and low at a high Ar pressure side by increasing the Ar pressure when the SiN undercoat layer is formed.

When the Ar pressure is 1.5 Pa or more, there is little change in the modulation degree, and it stabilizes. In this way, by changing the setting of the Ar pressure of the SiN undercoat layer, the modulation degree can be adjusted. This tendency of the change is roughly the same regardless the optical depth of the phase pits of the substrate. Here the optical depth of the phase pits was measured by AFM (Atomic Force Microscope) measurement equipment after the substrate is molded.

The reason why the modulation degree of the phase pits of the magneto-optical disk is changed depending on the Ar pressure of the SiN undercoat layer is that the phase pits of the substrate are processed by Ar sputtering. By changing the setup level of the Ar pressure, the plasma status in the film deposition chamber changes, and by this the processing conditions of the phase pits of the substrate surface change. As a result, the adjustment of the modulation degree becomes possible. In other words, the shapes of the phase pits can be substantially processed in the film deposition steps.

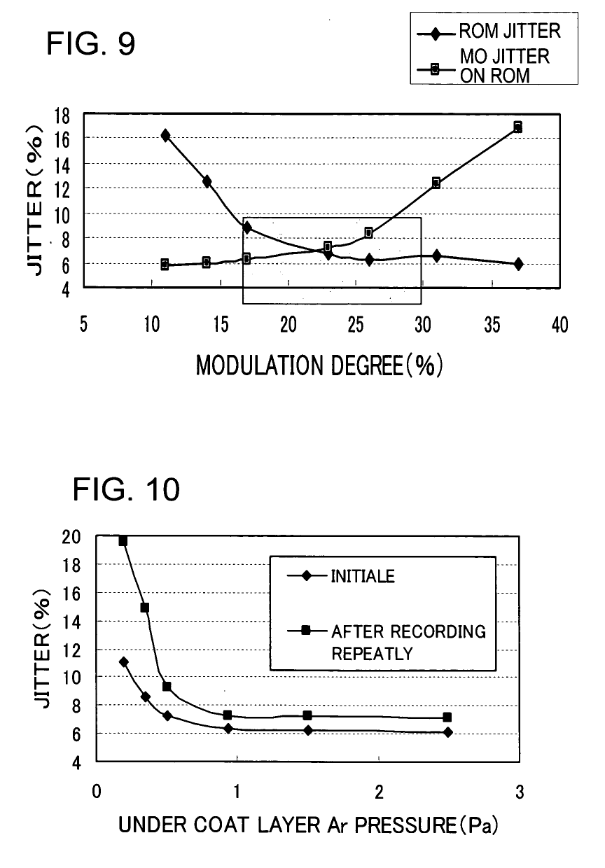

FIG. 9 is a graph depicting the modulation degree and the jitter when ROM jitter and MO (RAM) signal jitter on the ROM of the seven magneto-optical disk medium samples, with a modulation degree of 10 (%) to 37 (%) in FIG. 8 were measured, as described above.

As the modulation degree increases, the MO (RAM) signal jitter on the ROM increases, and as the modulation degree decreases the ROM jitter increases. On the circuit, jitter within the error correction limit is 15% or less, but if the aggravation of jitter by various fluctuation factors, such as disk rotation fluctuation, is considered, then a 10% or less jitter must be implemented.

According to the graph in FIG. 9, the modulation must be set between 16% and 30% to make the jitter of both ROM and MO (RAM) on ROM to be 10% or less. It is even more preferable if the modulation degree is set between 19% and 26% to make the jitter 8% or less.

FIG. 10 is a graph depicting the relationship between the jitter of MO (RAM) signals on ROM and Ar pressure when the undercoat layer is formed. For the jitter, the initial jitter and the jitter after 100,000 times of continuous recording testing is performed, were measured.

As FIG. 10 shows, if the Ar pressure is decreased (modulation degree is increased), the jitter of MO (RAM) signals on ROM radically increases, and the jitter of continuous recording also increases as the modulation degree of the ROM regeneration signal increases. As described in FIG. 9, Ar pressure must be set to 0.5 Pa or more to make the jitter after continuous recording to be 10% or less.

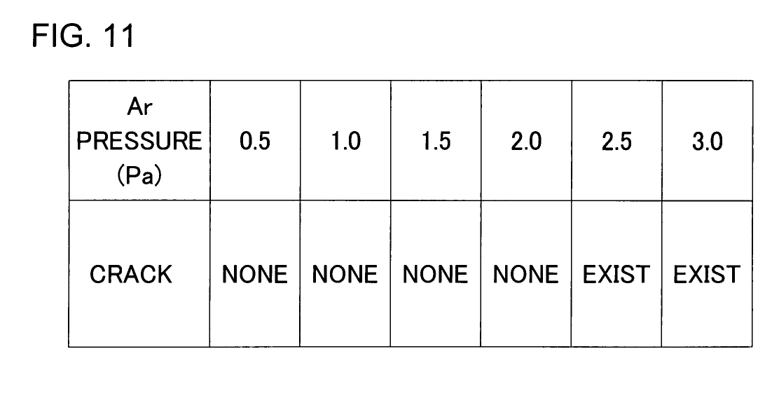

Then a heat shock test is performed on the sample where each layer, including the SiN undercoat layer, are deposited on the substrate 4A, as shown in FIG. 1, then the crack generation of the medium was observed. In other words, as FIG. 11 shows, samples were created with a plurality of Ar pressures to which the SiN undercoat layer was created, and were moved from room temperature to a 100° C. environment and held there for one hour, then were returned to the room temperature environment and crack generation was observed. As FIG. 11 shows, the range where cracks are not generated in the SiN undercoat layer is at Ar pressure 2.0 Pa or less.

As the results in FIG. 9, FIG. 10 and FIG. 11 show, in order to obtain good signal quality for both ROM signals and RAM (MO on ROM) signals without generating cracks, conditions within the frame in FIG. 8 must be met.

For example, in the case of a substrate with a 0.124λ optical pit depth, the Ar pressure is set between 0.7 to 2.0 (Pa). In the case of a 0.080λ optical pit depth, the Ar pressure is set between 0.5 and 1.5 (Pa). And in the case of substrates with a 0.070λ and 0.136λ optical pit depth, the modulation degree cannot be set between 16 and 30% even if the Ar pressure is set between 0.5 and 2.0 (Pa).

In the case of the substrate with a 0.105λ optical pit depth, the modulation degree becomes a range from 16 to 30% with any of 0.5 to 2.0 (Pa) Ar pressure. Conditions with which the jitter of both ROM signals and RAM signals become the optimum is the modulation degree 23%, and with this substrate, an even higher level quality can be implemented by setting the Ar pressure between 0.6 and 1.0 Pa.

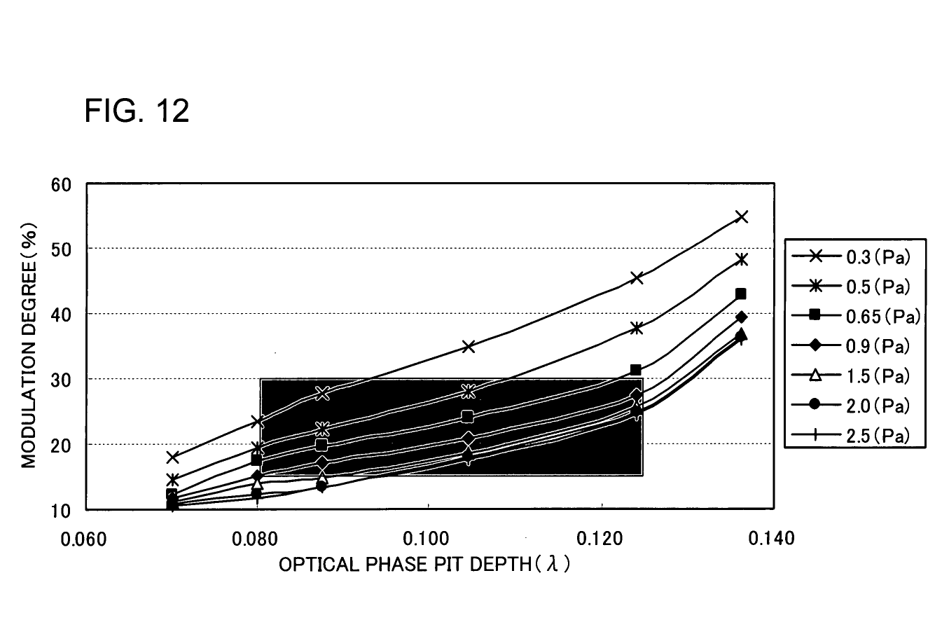

FIG. 12 shows the result when the change of modulation degree with respect to the optical phase pit depth is plotted for each Ar pressure when the under coat SiN is deposited, which is the opposite of FIG. 8. In FIG. 12, when the optical phase pit depth, when the substrate is molded, is 0.080λ, the modulation degree can be adjusted in a range of 16 to 30% by adjusting the Ar pressure in the a range of 0.5 to 0.9 (Pa). It is preferable that the modulation degree is adjusted to roughly 19% by setting the Ar pressure to 0.5 (Pa).

Whereas when the optical pit depth is a deeper 0.124λ, the modulation degree in a range of 16 to 30% can be implemented by setting the Ar pressure when the under coat SiN film is deposited at a range of 0.9 to 2.0 (Pa). It is preferable that the modulation degree is adjusted to roughly 26% by setting the Ar pressure to 2.0 (Pa).

When the phase pit depth is at mid-level 0.105λ, a 16 to 30% demodulation degree can be implemented in an Ar pressure range of 0.5 to 2.0 (Pa). It is preferable that a 19-26% modulation degree is implemented by adjusting the Ar pressure in a range of 0.65 to 1.5 (Pa).

When the depth of the optical phase pits becomes shallow, to 0.080λ or less, the adjustable range of the modulation degree becomes narrow, and a 19 to 30% modulation degree cannot be implemented. For phase pits with a 0.124λ or deeper as well, the modulation degree adjustable range becomes narrow, and a 19 to 30% modulation degree cannot be implemented.

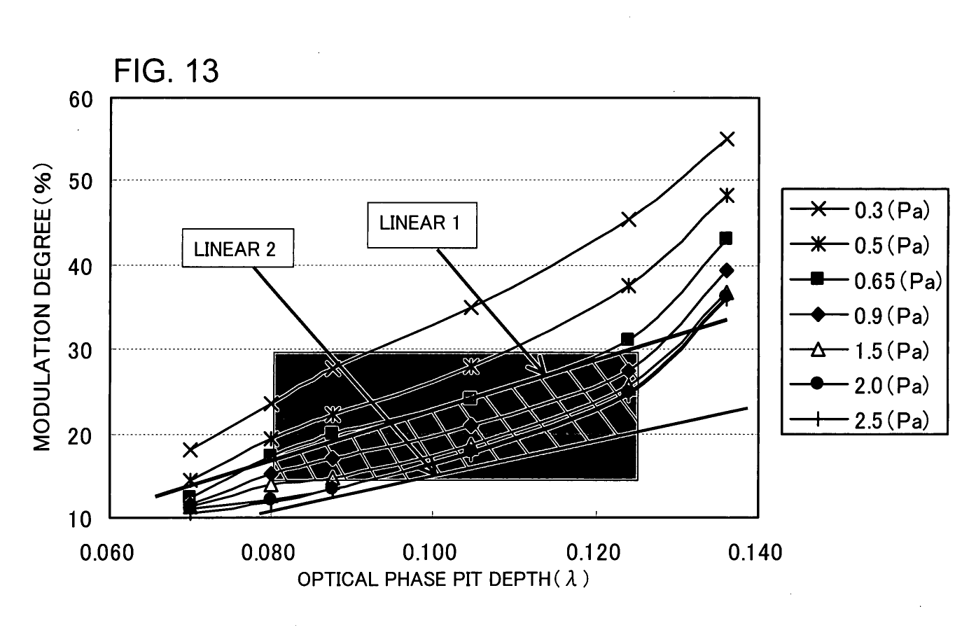

FIG. 13 is a characteristic diagram considering the above mentioned repeat recording characteristics in FIG. 10, and the crack generation in FIG. 11 related to FIG. 12. In other words, FIG. 13 shows the setup range of the phase pit depth and modulation degree with which the magneto-optical medium, which can regenerate ROM and RAM simultaneously where 10% or less of good jitter is implanted for both ROM and RAM signals without generating cracks with sufficient recording durability, can be implemented.

In FIG. 13, line 1 is determined from the repeat characteristics in FIG. 10, and line 2 is determined by the crack observation result of the heat shock test in FIG. 11. Therefore as FIG. 13 shows, the above mentioned setup range is a range between the following two lines 1 and 2, and the optical depth of the phase pits is from 0.080λ to 0.124λ, and the modulation degree is in a range of 16 to 30%, preferable a range of 19 to 26%.
Line 1: Y=344x−8.12
Line 2: Y=286x−10.7

In the present embodiment, the sputtering film deposition steps using SiN was described as an example, but other materials can be used only if it is a material of which the modulation degree can be adjusted. SiO₂, AlN, SiA₁₀, SiA₁₀N and TaO, for example, can be used.

Other Embodiments

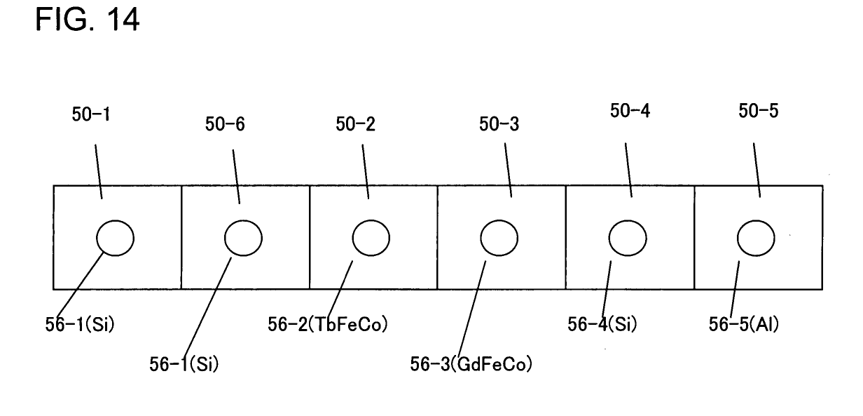

FIG. 14 is a diagram depicting the configuration of the sputtering film deposition device according to another embodiment of the present invention. In FIG. 14, composing elements the same as FIG. 5 are denoted with the same reference numerals. In this embodiment, the under coat SiN layer 4B, of which the film thickness is thick, may drop productivity, so a sixth chamber 50-6 is installed in the first chamber 50-1, and the Si target 56-1 is set for both of these chambers, so that the SiN undercoat layer 4B is. deposited in two steps. In this case, the Ar gas pressure may be different between the first chamber 50-1 and the sixth chamber 50-6.

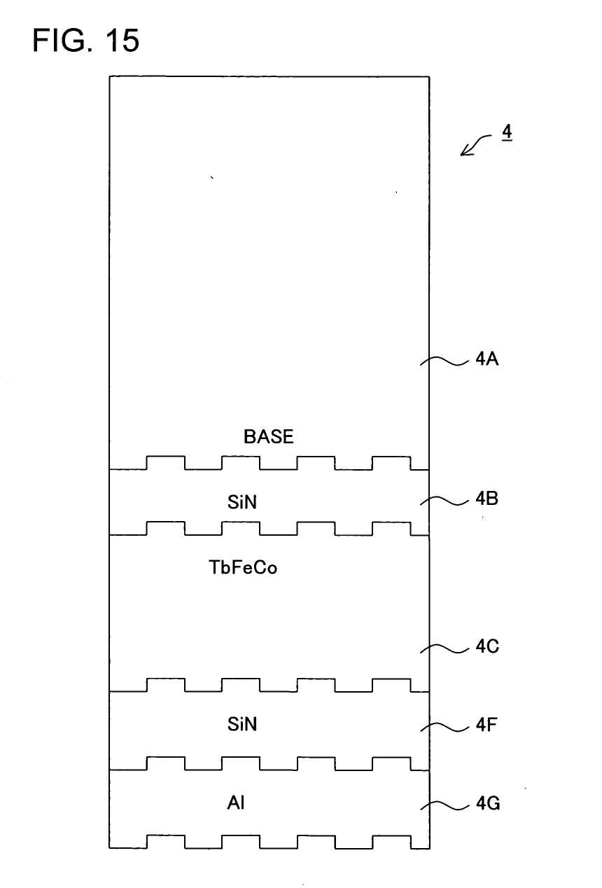

FIG. 15 is a cross-sectional view depicting the concurrent magneto-optical recording medium according to another embodiment of the present invention.

As FIG. 15 shows, in order to provide the functions of ROM and RAM in the user area, the magneto-optical disk 4 is comprised of the first dielectric layer 4B made from silicon nitride (SiN) or tantalum oxide, one layer of magneto-optical recording layer 4C made from an amorphous alloy of rare earth elements (Tb, Dy, Gd), such as TbFeCo and GdFeCo, second dielectric layer 4F made from the same material as the first dielectric layer 4B, reflection layer 4G made from such metal as Al and Au, and protective coat layer using ultraviolet hardening type resin, which are formed on the polycarbonate substrate 4A on which phase pits 1 are formed.

In other words, the magneto-optical recording layer is a single layer. With this example as well, the modulation degree of the phase pits can be adjusted in the sputtering film deposition step.

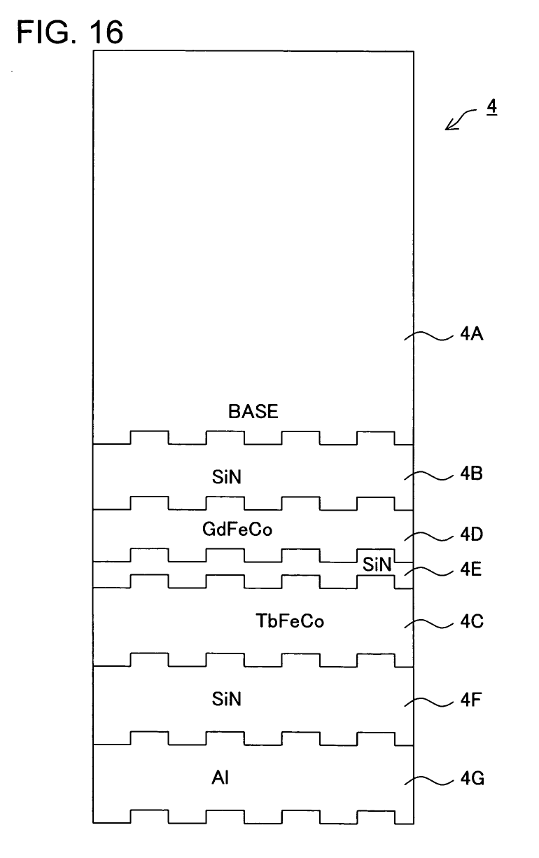

FIG. 16 is a cross-sectional view of the magneto-optical recording medium 4 according to still another embodiment of the present invention, and shows the medium for MSR (ultra high resolution recording). The magneto-optical layer formed on the first dielectric layer 4B on the substrate 4A is comprised of the GdFeCo layer (in-plane) 4D, dielectric layer 4E and vertical recording layer (TbFeCo) 4C.

In this recording medium with this configuration as well, the modulation degree of the phase pits can be adjusted by the sputtering film deposition step. The conditions described in FIG. 8 and later on the optical phase pit depth and modulation degree can be used. In the case of MSR, noise cannot be decreased even if the light intensity modulation signals are negatively fed back to the light emitting laser, since the recording density is high, so the effect of the present invention is obvious.

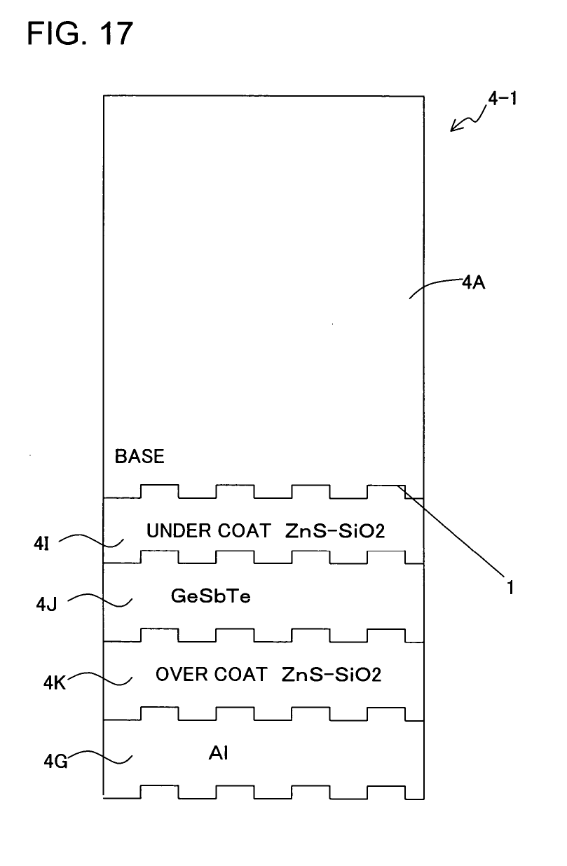

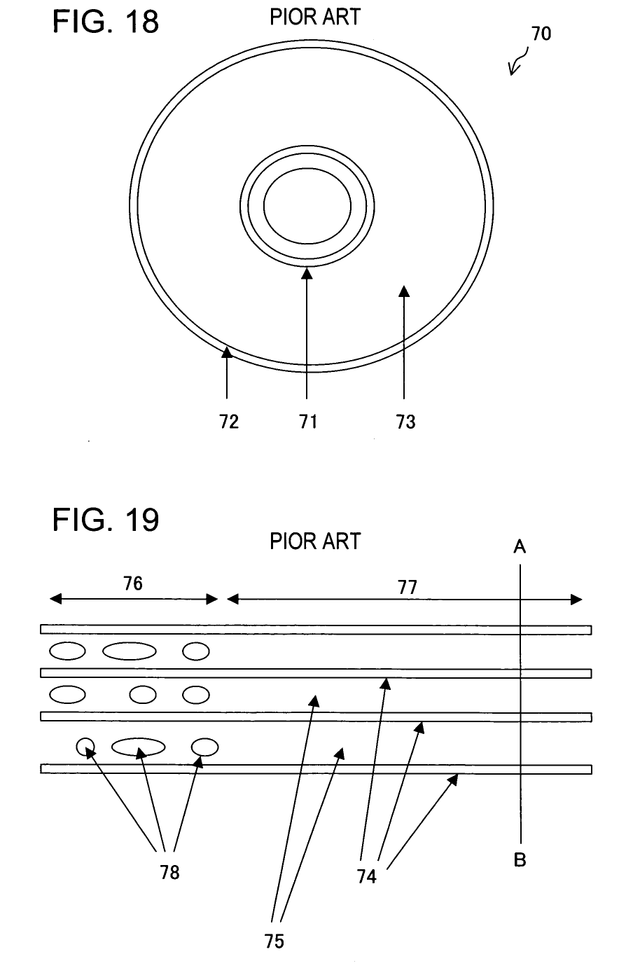

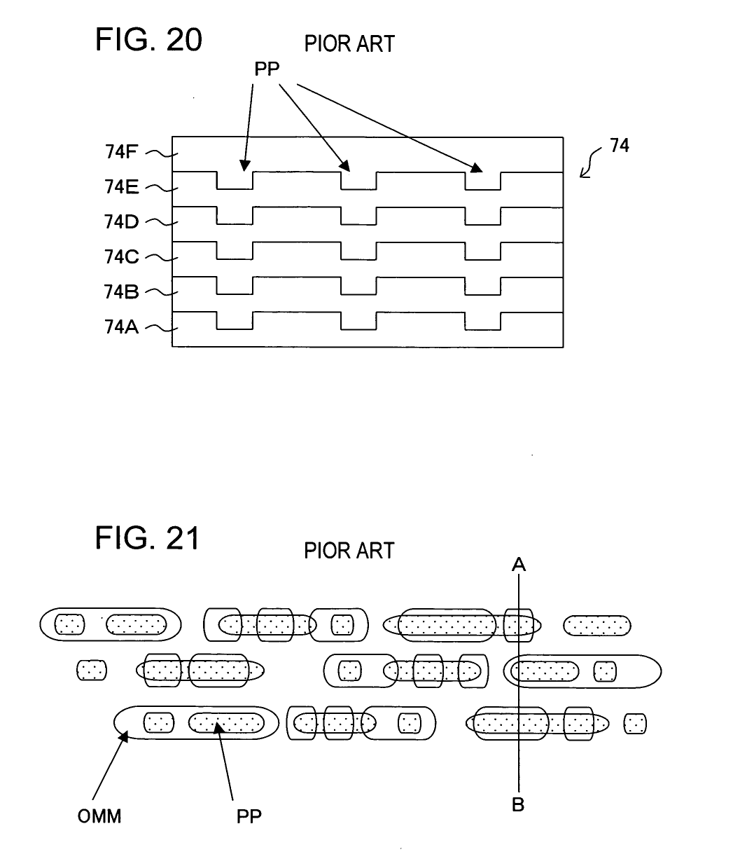

FIG. 17 is a cross-sectional view depicting the magneto-optical recording medium 4 according to still another embodiment of the present invention, and shows the phase change medium. The phase change medium, where the undercoat layer 4I (ZnS—SiO₂) is formed on the substrate 4A and on which phase pits are formed, is comprised of the GdSbTe layer 4J which is a phase change layer, overcoat layer 4K (ZnS—SiO₂) and Al layer 4G.

In this recording medium with this configuration as well, the modulation degree of phase pits can be adjusted in the sputtering film deposition step. The conditions described in FIG. 8 and later on optical phase pit depth and modulation degree can be used.

The present invention was described with the embodiments, but the present invention can be modified in various ways within the essential character of the present invention, and these modifications shall not be excluded from the technical scope of the present invention. The size of the phase pits, for example, is not limited to the above mentioned numeric values, but can be other values. For the magneto-optical recording film, other magneto-optical recording materials can be used. The magneto-optical recording medium is not limited to a disk shape, but such a shape as a card can be used. The inactive gas is not limited to Ar, but Xe and Kr can be used. The present invention can also be applied to the ROM-RAM recording medium where areas of the RAM layer and ROM layer are divided by a disk face.

### INDUSTRIAL APPLICABILITY

The present invention can be implemented by the configuration of the medium, easily and stably.

1. A manufacturing method for an optical recording medium where a recording film is formed on optical phase pits formed on a substrate so that both said optical phase pit signals and signals of said recording film can be regenerated by light, comprising steps of:
depositing said recording film by sputtering on said substrate on which said optical phase pits are formed by introducing an inactive gas into a chamber for depositing said recording film by; and
depositing a reflection layer by sputtering on the substrate on which said recording film is formed,
and wherein said depositing said recording film step comprising a step of adjusting the light modulation degree of said phase pits by changing the pressure of said inactive gas in said chamber when said recording film is deposited by sputtering.

2. The manufacturing method for an optical recording medium according to claim 1, wherein said step of depositing said recording film by sputtering further comprises the steps of:
changing the light modulation degree of said phase pits by depositing an undercoat layer of said recording film on said substrate by sputtering with changing the pressure of said inactive gas in said chamber; and
depositing said recording film by sputtering on said substrate on which said undercoat layer has been formed.

3. The manufacturing method for an optical recording medium according to claim 2, wherein the undercoat layer of said recording film deposited by said sputtering is a dielectric layer.

4. The manufacturing method for an optical recording medium according to claim 3, wherein the undercoat layer of said recording film deposited by sputtering is SiN.

5. The manufacturing method for an optical recording medium according to claim 4, wherein said step for depositing the undercoat layer by sputtering is a step of introducing at least Ar gas and nitrogen gas into said chamber for depositing said undercoat layer.

6. The manufacturing method for an optical recording medium according to claim 5, wherein said step of depositing the undercoat layer is a step of depositing said undercoat layer by sputtering with a gas pressure in said chamber in a range of 0.5 to 2.0 Pa.

7. The manufacturing method for an optical recording medium according to claim 3, wherein said step of depositing the recording film by sputtering further comprises a step of depositing a magneto-optical recording film by sputtering.

8. The manufacturing method for an optical recording medium according to claim 3, further comprising a step of depositing an overcoat layer on said recording film.

9. The manufacturing method for an optical recording medium according to claim 3, wherein said step of depositing said undercoat layer by sputtering is a step of depositing the under layer by sputtering under sputtering conditions that satisfy
344X−8.12≧Y and Y≧286X−10.7
0.080≦X≦0.124 and 16≦Y≦30
where X (λ) is the optical depth of the phase pits formed on said substrate and Y (%) is the modulation degree of said phase pits when irradiated with an optical beam in the polarization direction perpendicular to the tracks of said optical recording medium.

10. The manufacturing method for an optical recording medium according to claim 9, wherein said step of depositing the undercoat layer by sputtering is a step of depositing the undercoat layer by sputtering under sputtering conditions where the magneto-optical recording medium satisfies the condition
19≦Y≦26
out of said conditions.

11. A manufacturing device for an optical recording medium for forming a recording film on the optical phase pits formed on a substrate so that both said optical phase pit signals and the signals of said recording film can be regenerated by light, comprising:
a first sputtering device for introducing an inactive gas into a chamber and depositing said recording film by sputtering on the substrate on which said optical phase pits are formed; and
a second sputtering device for depositing a reflection layer by sputtering on the substrate on which said recording film is formed,
and wherein said first sputtering device adjusts the light modulation degree of said phase pits by changing the pressure of said inactive gas in said chamber.

12. The manufacturing device for an optical recording medium according to claim 11, wherein said first sputtering device further comprises:
a third sputtering device which changes the pressure of said inactive gas in said chamber for depositing an undercoat layer of said recording film on said substrate by sputtering for changing the light modulation degree of said phase pits; and
a fourth sputtering device for depositing said recording film by sputtering on said substrate on which said undercoat layer has been formed.

13. The manufacturing device for an optical recording medium according to claim 12, wherein said third sputtering device deposits said undercoat layer made of a dielectric layer by sputtering.

14. The manufacturing device for an optical recording medium according to claim 13, wherein said third sputtering device deposits SiN by sputtering as said undercoat layer.

15. The manufacturing device for an optical recording medium according to claim 14, wherein said third sputtering device introduces at least an Ar gas and nitrogen gas into said chamber for depositing said undercoat layer by sputtering.

16. The manufacturing device for an optical recording medium according to claim 15, wherein said third sputtering device deposits said undercoat layer by sputtering with gas pressure in said chamber in a range of 0.5 to 2.0 Pa.

17. The manufacturing device for an optical recording medium according to claim 13, wherein said fourth sputtering device deposits a magneto-optical recording film by sputtering.

18. The manufacturing device for an optical recording medium according to claim 13, further comprising a fifth sputtering device for depositing an overcoat layer on said recording film by sputtering.
